(19) United States
(12) Patent Application Publication
(10) Pub. No.: US 2023/0106276 A1
(43) Pub. Date: Apr. 6, 2023

(54) ORGANIC LIGHT-EMITTING DIODE SUBSTRATE AND MANUFACTURING METHOD THEREOF

(71) Applicant: Shenzhen China Star Optoelectronics Semiconductor Display Technology Co., Ltd., Shenzhen, Guangdong (CN)

(72) Inventor: Guojie WANG, Shenzhen, Guangdong (CN)

(21) Appl. No.: 17/615,177

(22) PCT Filed: Oct. 20, 2021
(86) PCT No.: PCT/CN2021/124994

§ 371 Date: Nov. 30, 2021

(30) Foreign Application Priority Data
Sep. 26, 2021 (CN) 202111126769.4

(51) Int. Cl. H01L 27/32; H01L 51/56; H01L 51/00

(52) U.S. Cl. CPC H01L 27/3248; H01L 27/3223; H01L 27/3246; H01L 51/0005; H01L 51/56; H01L 2227/323

(57) ABSTRACT

An organic light-emitting diode substrate and a manufacturing method thereof are provided. The organic light-emitting diode substrate includes a substrate, a thin-film transistor element layer, an anode layer, a pixel definition layer, a light-emitting functional layer, and a cathode layer, wherein, a plurality of pixel electrodes, the light-emitting functional layer, and the cathode layer form a plurality of pixel unit rows under definition of a plurality of pixel grooves, and wherein a plurality of dummy pixel units are arranged outside at least one side of an upper side, a lower side, a left side, or a right side of the plurality of pixel unit rows.

### FIELD OF INVENTION

The present invention relates to a field of display technology, particularly relates to an organic light-emitting diode substrate and a manufacturing method thereof.

### BACKGROUND OF INVENTION

Organic light-emitting diodes (OLED) namely organic electroluminescent displays (OELD) technology was first studied by French and Americans in the 1950s and 1960s. OLED generates light through an injection and a recombination of charge carriers, that is, under an action of an electric field, holes generated by an anode and electrons generated by a cathode will migrate and are injected into a hole transport layer and an electron transport layer respectively, and then they migrate to a light-emitting layer. When two of them encounter in the light-emitting layer, excitons are generated, which excites light-emitting molecules and finally generates visible light. OLED devices have advantages of self-luminescence, wide viewing angles, high contrast ratio, low power consumption, fast response times, full color, and lightness and thinness.

Compared with use of fine metal mask evaporation film forming process to manufacture the OLED devices, use of inkjet printing technology to manufacture OLED devices has attracted much attention because of its precise alignment, no metal mask required, and material utilization rate of 100%. It has become a mainstream trend in manufacturing of large-size OLED devices in the future.

### Technical Problem

The pixel array of traditional organic light-emitting diodes is composed of a plurality of dot-shaped pixels. Each pixel unit includes a red sub-pixel (R), a green sub-pixel (G), and a blue sub-pixel (B). The R, G, and B sub-pixels are arranged repeatedly in sequence to form a matrix. This traditional dot-shaped pixels arrangement structure is likely to cause mura phenomenon due to a large difference in film thickness between the pixel units. The linear pixel definition layer (LPDL) solution can distribute ink droplets with different volumes dispensed by different nozzles to linear grooves defined by the pixel definition layer, which achieves an object of small differences in the thickness of an overall pixel film layer and effectively prevents the mura phenomenon from occurring. However, because the LPDL solution distributes ink droplets with different volumes dispensed from different nozzles to the linear grooves defined by the pixel definition layer, this causes it difficult to monitor whether the inkjet volume from each nozzle is normal during the inkjet printing process. Therefore, if the printed volume of some of the nozzles is too large or too small, the film thickness of overall pixel after drying will be too thick or too thin, which will reduce the yield or affect the performance of the devices.

Therefore, the LPDL solution in the current inkjet printing technology cannot immediately monitor whether the inkjet volume of each nozzle is normal, and the problem that the film thickness of the overall pixel is too thick or too thin needs to be further solved.

### SUMMARY OF INVENTION

In order to solve the aforesaid problems, the present invention provides an organic light-emitting diode substrate and a manufacturing method thereof. In the present invention, dummy pixel units are provided outside at least one side of a plurality of pixel unit rows, or a pixel dot sub-portion is provided at the outermost pixel unit at one end of each pixel unit row, wherein the pixel dot sub-portion occupies ⅓ to ½ of an area of the pixel electrode. With the aforesaid method to provide smaller dummy pixel units or pixel dot sub-portions, it is easy to monitor whether the inkjet volume of each nozzle is normal in the process of inkjet printing. Therefore, it can solve the problem that in the current inkjet printing technology for the OLED devices, it is not possible to monitor whether the inkjet volume of each nozzle is normal because the linear pixel film layer is formed by mixing inks dispensed from multiple nozzles.

The present invention provides an organic light-emitting diode substrate. The organic light-emitting diode substrate includes: a substrate; a thin film transistor element layer disposed on the substrate; an anode layer disposed on the thin film transistor element layer, wherein the anode layer includes a plurality of pixel electrodes arranged in an array and a plurality of dummy pixel electrodes, and each pixel electrode is electrically connected to a corresponding thin-film transistor in the thin film transistor element layer; a pixel definition layer, wherein the pixel definition layer is defined with a plurality of linear pixel grooves and a plurality of dot-shaped dummy pixel grooves on the anode layer; a light-emitting functional layer disposed on the anode layer in the plurality of pixel grooves and the plurality of dummy pixel grooves; and a cathode layer disposed on the light-emitting functional layer; and wherein the plurality of pixel electrodes, the light-emitting functional layer, and the cathode layer form a plurality of pixel unit rows under the definition of the plurality of pixel grooves, and the plurality of dummy pixel electrodes, the light-emitting functional layer, and the cathode layer form a plurality of dummy pixel units under the definition of the dummy pixel grooves.

In the organic light-emitting diode substrate according to an embodiment of the present invention, wherein the organic light-emitting diode substrate further includes a buffer layer disposed between the thin film transistor element layer and the anode layer.

In the organic light-emitting diode substrate according to an embodiment of the present invention, wherein the light-emitting functional layer includes a hole injection layer, a hole transport layer, a luminescent material layer, an electron transport layer, and an electron injection layer.

In the organic light-emitting diode substrate according to an embodiment of the present invention, wherein the dummy pixel units are arranged outside an upper side and/or a lower side of the plurality of pixel unit rows.

In the organic light-emitting diode substrate according to an embodiment of the present invention, further including another dummy pixel units arranged outside a left side and/or a right side of the plurality of pixel unit rows.

In the organic light-emitting diode substrate according to an embodiment of the present invention, the dummy pixel units are arranged outside the left side and/or the right side of the plurality of pixel unit rows in a way that one dummy pixel unit corresponds to one pixel unit row.

In the organic light-emitting diode substrate according to an embodiment of the present invention, the dummy pixel units are arranged outside the left side and/or the right side of the plurality of pixel unit rows in a way that two dummy pixel units correspond to one pixel unit row.

In the organic light-emitting diode substrate according to an embodiment of the present invention, the two dummy pixel units are arranged side by side.

In the organic light-emitting diode substrate according to an embodiment of the present invention, types of luminescent material layers of the two dummy pixel units are the same.

The present invention further provides another organic light-emitting diode substrate, the organic light-emitting diode substrate includes: a substrate; a thin film transistor element layer disposed on the substrate; an anode layer disposed on the thin film transistor element layer, wherein the anode layer includes pixel electrodes arranged in an array, and each pixel electrode is electrically connected to a corresponding thin-film transistor in the thin film transistor element layer; a pixel definition layer, wherein the pixel definition layer is defined with linear first pixel grooves and dot-shaped second pixel grooves on the anode layer; a light-emitting functional layer disposed on the anode layer in the first pixel grooves and the second pixel grooves; and a cathode layer disposed on the light-emitting functional layer; wherein the pixel electrodes, the light-emitting functional layer, and the cathode layer form a plurality of pixel unit rows under the definition of the first pixel grooves, and the outermost pixel unit at one end of each pixel unit row forms a pixel dot sub-portion under the definition of the second pixel groove.

In the organic light-emitting diode substrate according to an embodiment of the present invention, the pixel dot sub-portion occupies ⅓ to ½ of an area of the pixel electrode.

In the organic light-emitting diode substrate according to an embodiment of the present invention, further including a buffer layer disposed between the thin film transistor element layer and the anode layer.

In the organic light-emitting diode substrate according to an embodiment of the present invention, the light-emitting functional layer includes a hole injection layer, a hole transport layer, a luminescent material layer, an electron transport layer, and an electron injection layer.

The present invention further provides a manufacturing method of an organic light-emitting diode substrate, the manufacturing method includes following steps: providing a substrate and forming a thin film transistor element layer on the substrate; forming a planarization layer on the thin film transistor element layer; forming an anode layer on the planarization layer; forming a pixel definition layer on the planarization layer and the anode layer, wherein the pixel definition layer includes a plurality of linear pixel grooves and a plurality of dot-shaped dummy pixel grooves; forming a hole injection layer on the anode layer in the plurality of pixel grooves and the plurality of dummy pixel grooves by inkjet printing; checking whether printing volumes for forming the hole injection layer in the plurality of dummy pixel grooves is normal, if yes, proceeding to a next step, if not, stop production and checking nozzles; performing a drying treatment on the hole injection layer; forming a hole transport layer on the hole injection layer by inkjet printing; checking whether printing volumes for forming the hole transport layer in the plurality of dummy pixel grooves is normal, if yes, proceeding to a next step, if not, stop the production and checking the nozzles; performing a drying treatment on the hole transport layer; forming a luminescent material layer on the hole transport layer by inkjet printing; checking whether printing volumes for forming the luminescent material layer in the plurality of dummy pixel grooves is normal, if yes, proceeding to a next step, if not, stop the production and checking the nozzles; performing a drying treatment on the luminescent material layer; forming an electron transport layer on the luminescent material layer; forming an electron injection layer on the electron transport layer; and forming a cathode layer on the electron injection layer.

### Beneficial Effect

In the organic light-emitting diode substrate and the manufacturing method thereof, dummy pixel units are provided outside at least one side of the pixel unit rows, or pixel dot sub-portions are formed under the limitation of the second pixel groove at the outermost pixel unit at one end of each pixel unit row, wherein the pixel dot sub-portion occupies ⅓ to ½ of an area of the pixel electrode. Through the method to provide the aforesaid small dummy pixel units or the pixel dot sub-portions, it is easy to monitor whether the inkjet volume of each nozzle is normal during the process of inkjet printing. Therefore, it can solve the problem that in the current inkjet printing technology for the OLED devices, it is not possible to monitor whether the inkjet volume of each nozzle is normal because the linear pixel film layer is formed by mixing inks dispensed from multiple nozzles, which leads to low production yield due to insufficient film thickness or uneven film thickness of the entire batch of products.

### DESCRIPTION OF DRAWINGS

FIG. 1 is a schematic top view of an organic light-emitting diode substrate according to a first embodiment of the present invention.

FIG. 2 is a schematic top view of an organic light-emitting diode substrate according to a second embodiment of the present invention.

FIG. 3 is a partial schematic view of the organic light-emitting diode substrate in FIG. 2.

FIG. 4 is a schematic diagram of a cross-sectional structure of the organic light-emitting diode substrate taken along a line A-A′ in FIG. 3.

FIG. 5 is a partial schematic diagram of a top view of an organic light-emitting diode substrate according to a third embodiment of the present invention.

FIG. 6 is a schematic diagram of a cross-sectional structure of the organic light-emitting diode substrate taken along a line B-Bʹ in FIG. 5.

FIG. 7 is a partial schematic diagram of a top view of an organic light-emitting diode substrate according to a fourth embodiment of the present invention.

FIG. 8 is a schematic cross-sectional structure diagram of the organic light-emitting diode substrate taken along a line C-Cʹ in FIG. 7.

FIG. 9 is a flowchart of a manufacturing method of an organic light-emitting diode substrate according to an embodiment of the present invention.

### DETAILED DESCRIPTION OF PREFERRED EMBODIMENTS

The following describes in detail the organic light-emitting diode substrate and the manufacturing method thereof provided by the embodiments of the present invention with reference to the accompanying drawings. Obviously, the embodiments are only a part of the embodiments of the present invention, rather than all the embodiments. Based on the embodiments of the present invention, all other embodiments obtained by those of ordinary skill in the art without doing creative work shall fall within the protection scope of the present invention.

The description of the following embodiments refers to the drawings to illustrate specific embodiments in which the present invention can be implemented. The directional terms mentioned in the present invention, such as “above”, “below”, “front”, “back”, “left”, “right”, “inner”, “outer”, “side”, etc., are only directions for the attached drawings. Therefore, the directional terms are used to describe and understand the present invention, rather than to limit the present invention. In the drawings, for clear understanding and ease of description, the thickness of some layers and the number and size of some components are exaggerated. That is, the number, size, and thickness of each component shown in the drawings are arbitrarily shown, but the present invention is not limited thereto.

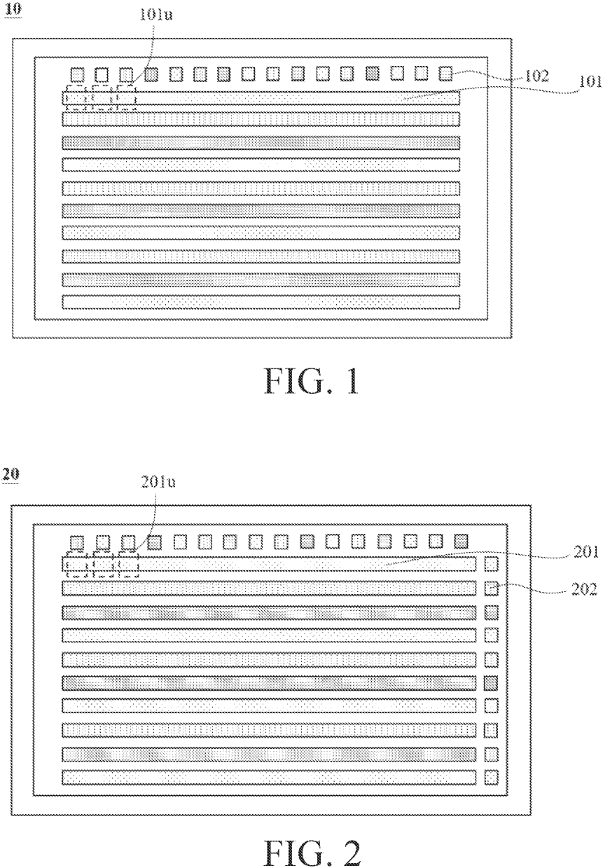

Please refer to FIG. 1, which is a schematic top view of the organic light-emitting diode substrate according to the first embodiment of the present invention. The organic light-emitting diode substrate 10 includes a plurality of linear pixel unit row 101 and a plurality of dummy pixel units 102. The plurality of linear pixel unit row 101 span at least 85% of the length of the effective display area of the entire organic light-emitting diode substrate. Each pixel unit row 101 includes a plurality of pixel units 101u. The plurality of dummy pixel units 102 are arranged outside an upper side and/or a lower side of the plurality of pixel unit rows 101.

In this embodiment, the plurality of dummy pixel units 102 are arranged outside the upper side and/or the lower side of the plurality of pixel unit rows 101. Because the inkjet volume of the dummy pixel unit 102 is small and is presented in a dot-like form, it is easy to monitor whether the corresponding nozzle has an abnormal dispensing volume. In addition, since the arrangement direction of the dummy pixel units 102 is the same as the arrangement direction of the printing nozzles, it can be set that each dummy pixel unit corresponds to one printing nozzle to facilitate the confirmation of abnormal printing nozzles.

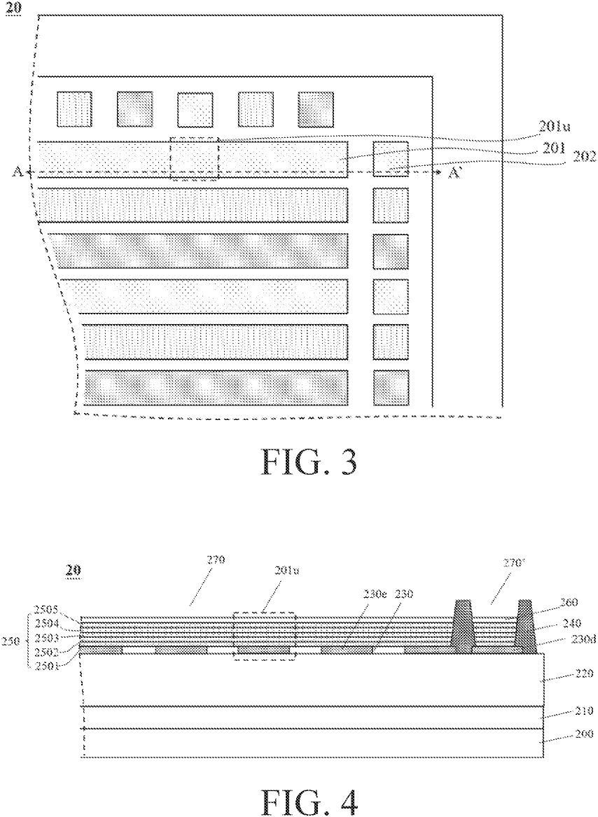

Please refer to FIG. 2, which is a schematic top view of the organic light-emitting diode substrate according to the second embodiment of the present invention. Please refer to FIG. 3 and FIG. 4 together. FIG. 3 is a partial schematic diagram of the organic light-emitting diode substrate shown in FIG. 2. FIG. 4 is a schematic diagram of a cross-sectional structure of the organic light-emitting diode substrate taken along a line A-Aʹ in FIG. 3. As shown in FIG. 3, the organic light-emitting diode substrate 20 further includes a plurality of dummy pixel units 202 arranged outside at least one of the left side and right side of the plurality of pixel unit rows 201. The plurality of dummy pixel units 202 are arranged outside at least one of the left side and right side of the plurality of pixel unit rows 201 in a way that one dummy pixel unit 202 corresponds to one pixel unit row 201. As shown in FIG. 4, the organic light-emitting diode substrate 20 includes a substrate 200, a thin film transistor element layer 210 disposed on the substrate 200, and an anode layer 230 disposed on the thin film transistor element layer 210. The anode layer 230 includes a plurality of pixel electrodes 230e arranged in an array and a plurality of dummy pixel electrodes 230d, and the plurality of pixel electrodes 230e are respectively electrically connected to corresponding thin-film transistors in the thin film transistor element layer 210 (not shown in the figure). The organic light-emitting diode substrate 20 also includes: a pixel definition layer 240 which defines a plurality of linear pixel grooves 270 and a plurality of dot-shaped dummy pixel grooves 270ʹ on the anode layer 230; a light-emitting functional layer 250 disposed on the anode layer 230 in the plurality of pixel grooves 270 and the plurality of dummy pixel grooves 270'; and a cathode layer 260 disposed on the light-emitting functional layer 250. Wherein, the pixel electrodes 230e, the light-emitting functional layer 250, and the cathode layer 260 form a plurality of pixel unit rows 201 under the definition of the pixel grooves 270, and the dummy pixel electrodes 230d, the light-emitting functional layer 250, and the cathode layer 260 form a plurality of dummy pixel units 202 under the definition of the dummy pixel grooves 270ʹ. Wherein, each pixel unit row 201 includes a plurality of pixel units 201u.

Specifically, none of the plurality of dummy pixel units 230d is electrically connected to the thin film transistor in the thin film transistor element layer 210.

Preferably, the organic light-emitting diode substrate 20 further includes a buffer layer 220 disposed between the thin film transistor element layer 210 and the anode layer 230.

Preferably, the light-emitting functional layer includes a hole injection layer 2501, a hole transport layer 2502, a luminescent material layer 2503, an electron transport layer 2504, and an electron injection layer 2505 from bottom to top.

Preferably, the dummy pixel units 202 are arranged outside the left side and/or the right side of the plurality of pixel unit rows 201 in a way that one dummy pixel unit 202 corresponds to one pixel unit row 201.

Specifically, the total number of the plurality of dummy pixel units 202 is, for example, 10 to 100, or more. The actual number can be determined according to the space of the effective display area and is not limited herein. The width of each of the plurality of dummy pixel units 202 may be the same as or different from the width of the pixel unit row 201. The length of each dummy pixel unit 202 can be ranged from 20 µm to 200 µm, for example, 25 µm.

In this embodiment, the plurality of dummy pixel units 202 are arranged outside at least one side of the plurality of pixel unit rows 201 in a manner that one dummy pixel unit 202 corresponds to one pixel unit row 201. In the process of inkjet printing, whether the corresponding nozzle has an abnormal spray volume can be easily monitored by checking the dummy pixel units 202 arranged outside at least one side of the plurality of pixel unit rows 201 because the inkjet volume of the dummy pixel unit is small and is presented in a dot-like form.

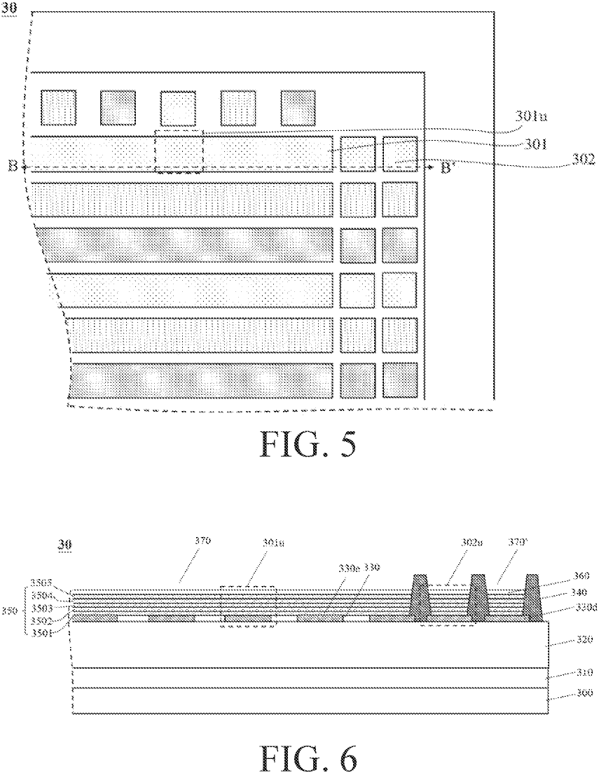

Please refer to FIG. 5 and FIG. 6 together. FIG. 5 is a partial schematic diagram of a top view of an organic light-emitting diode substrate according to a third embodiment of the present invention, and FIG. 6 is a schematic diagram of a cross-sectional structure of the organic light-emitting diode substrate taken along a line B-Bʹ in FIG. 5. As shown in FIG. 5, the organic light-emitting diode substrate 30 further includes another dummy pixel units 302 arranged outside a left side and/or a right side of the plurality of pixel unit rows 301. The dummy pixel units 302 are arranged outside the left side and/or the right side of the plurality of pixel unit rows 301 in a way that two dummy pixel units 302 correspond to one pixel unit row 301, and the two dummy pixel units 302 are arranged side by side.

As shown in FIG. 6, the organic light-emitting diode substrate 30 includes a substrate 300, a thin film transistor element layer 310 disposed on the substrate 300, and an anode layer 330 disposed on the thin film transistor element layer 310, wherein the anode layer 330 includes pixel electrodes 330e arranged in an array and a plurality of dummy pixel electrodes 330d, and each pixel electrode 330e is electrically connected to a corresponding thin-film transistor in the thin film transistor element layer 310 (not shown in the figure). The organic light-emitting diode substrate 30 also includes: a pixel definition layer 340 defined with a plurality of linear first pixel grooves 370 and a plurality of dot-shaped dummy pixel grooves 370' on the anode layer 330; a light-emitting functional layer 350 disposed on the anode layer 330 in the plurality of pixel grooves 370 and the plurality of dummy pixel grooves 370ʹ; and a cathode layer 360 disposed on the light-emitting functional layer 350. Wherein the pixel electrodes 330e, the light-emitting functional layer 350, and the cathode layer 360 form a plurality of pixel unit rows 301 under the definition of the pixel grooves 370, and the plurality of dummy pixel electrodes 330d, the light-emitting functional layer 350, and the cathode layer 360 form a plurality of dummy pixel units 302u under the definition of the plurality of dummy pixel grooves 370ʹ. Specifically, none of the plurality of dummy pixel units 330d need to be electrically connected to the thin-film transistors in the thin film transistor element layer 310.

Specifically, the light-emitting functional layer 350 includes a hole injection layer 3501, a hole transport layer 3502, a luminescent material layer 3503, an electron transport layer 3504, and an electron injection layer 3505 arranged from bottom to top.

Preferably, the dummy pixel units 302 are arranged outside the left side and/or the right side of the plurality of pixel unit rows 301 in a way that two dummy pixel units 302 correspond to one pixel unit row 301. The two dummy pixel units 302 are arranged side by side.

Preferably, the types of luminescent material layers of the two dummy pixel units 302 are the same.

Because the types of luminescent material layers of the two dummy pixel units 302 are the same, the colors are the same, which facilitates comparison of whether the sizes of the two dummy pixel units 302 are different. The two dummy pixel units 302 can be formed through the dispensing of different nozzles, which is beneficial to compare whether the inkjet volumes of different nozzles have significant differences so that whether the dispensing volume of the nozzles is normal can be monitored.

In this embodiment, the plurality of dummy pixel units 302 are located outside the left and/or the right sides of the plurality of pixel unit rows 301 in a manner that two dummy pixel units 302 correspond to one pixel unit row 301. Furthermore, the two dummy pixel units 302 are arranged side by side. In this design, the two dummy pixel units 302 arranged side by side will be checked. The two dummy pixel units 302 can be set to be formed by the dispensing of different nozzles. By comparing the two dummy pixel units 302 arranged side by side, it is easier to find whether the two nozzles corresponding to the two dummy pixel units 302 have abnormal dispensing volumes.

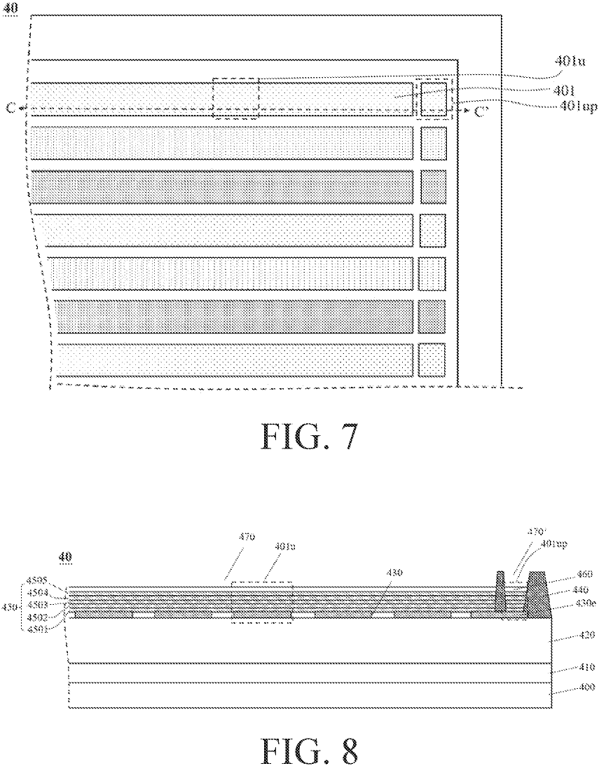

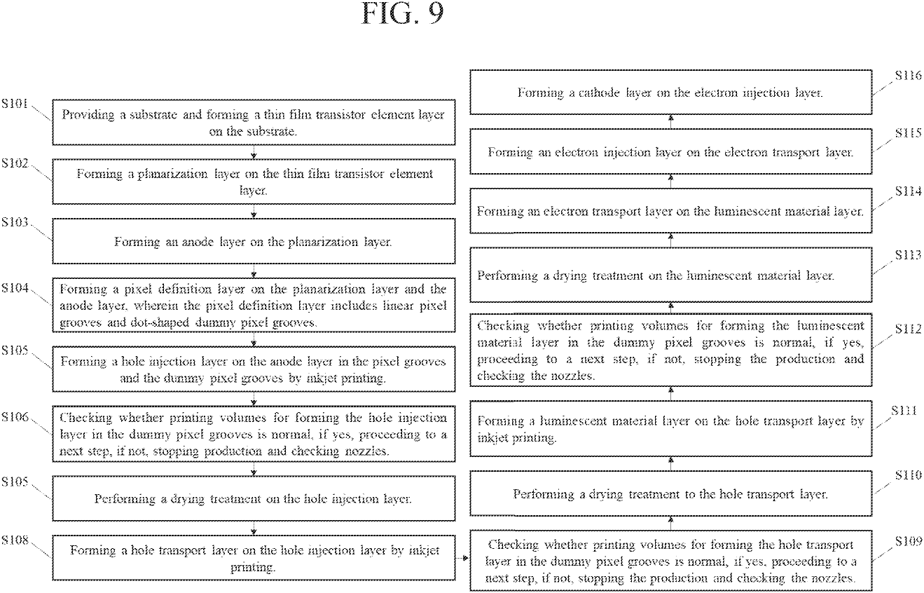

Please refer to FIG. 7 and FIG. 8 together. FIG. 7 is a partial schematic diagram of a top view of an organic light-emitting diode substrate 40 according to a fourth embodiment of the present invention. FIG. 8 is a schematic cross-sectional structure diagram of the organic light-emitting diode substrate 40 taken along a line C-Cʹ in FIG. 7. As shown in FIG. 8, the organic light-emitting diode substrate 40 includes a substrate 400, a thin film transistor element layer 410 disposed on the substrate 400, and an anode layer 430 disposed on the thin film transistor element layer 410. The anode layer 430 includes a plurality of pixel electrodes 430e arranged in an array and a plurality of dummy pixel electrodes 430d, and the plurality of pixel electrodes 430e are respectively electrically connected to corresponding thin-film transistors in the thin film transistor element layer 410 (not shown in the figure). The organic light-emitting diode substrate 40 also includes: a pixel definition layer 440 defined with a plurality of linear first pixel grooves 470 and a plurality of dot-shaped dummy pixel grooves 470ʹ on the anode layer 430; a light-emitting functional layer 450 disposed on the anode layer 430 in the plurality of pixel grooves 470 and the plurality of dummy pixel grooves 470ʹ; and a cathode layer 460 disposed on the light-emitting functional layer 450. Wherein, the pixel electrodes 430e, the light-emitting functional layer 450, and the cathode layer 460 form a plurality of linear pixel unit rows 401 under the definition of the first pixel grooves 470 (please refer to FIG. 7 together). Wherein, a part of an outermost pixel electrode at one end of each pixel unit row 401 is located in the first pixel groove 470, and a remaining part of the pixel electrode is located in the second pixel groove 470ʹ to form a pixel dot sub-portion 401 up. The pixel dot sub-portion occupies ⅓ to ½ of an area of the pixel electrode.

Specifically, the light-emitting functional layer 450 includes a hole injection layer 4501, a hole transport layer 4502, a luminescent material layer 4503, an electron transport layer 4504, and an electron injection layer 4505 arranged from bottom to top.

Preferably, the organic light-emitting diode substrate 40 further includes a buffer layer 420 disposed between the thin film transistor element layer 410 and the anode layer 430.

In this embodiment, it is different from the first embodiment to the third embodiment in which a dummy pixel unit is used to monitor whether the nozzle has an abnormal dispensing volume. In this embodiment, no dummy pixel unit is provided. In this embodiment, the outermost pixel unit at one end of each pixel unit row forms a pixel dot sub-portion under the limitation of the second pixel groove, wherein the pixel dot sub-portion occupies ⅓ to ½ of an area of the pixel electrode. By setting smaller pixel dot sub-portions, it is easy to monitor whether the inkjet volume of each nozzle is normal in the process of inkjet printing. Therefore, the problem that the current inkjet printing technology used for the OLED devices cannot monitor whether the inkjet volume of each nozzle is normal because the linear structure of the pixel film layer is formed by mixing ink from multiple nozzles is solved.

Furthermore, compared with the first embodiment to the third embodiment, this embodiment does not need to provide a dummy pixel unit. Instead, a pixel dot sub-portion is formed in the outermost pixel unit at one end of each pixel unit row. Because the distance between the pixel dot sub-portion and the end portion of the pixel unit row is small, the Influence on the display effect is hardly noticed by the naked eye. In this embodiment, there is no need to provide dummy pixels. In addition, because the dummy pixels are not powered on and emit light, a part of the effective display area must be sacrificed to provide the dummy pixels. Therefore, this embodiment can more efficiently utilize the effective display area of the organic light emitting diode substrate, which is more conducive to the realization of a narrow frame or a full screen displayer.

Please refer to FIG. 9. FIG. 9 is a flowchart of a manufacturing method of an organic light-emitting diode substrate according to an embodiment of the present invention. The manufacturing method of the organic light-emitting diode substrate includes:
S101, providing a substrate and forming a thin film transistor element layer on the substrate. Specifically, the substrate is a glass substrate, and the thin film transistor element layer may be a thin film transistor element layer prepared by low-temperature polycrystalline silicon (LTPS) or by indium gallium zinc oxide technology.
S102, forming a planarization layer on the thin film transistor element layer. Specifically, the planarization layer may be formed by, for example, sputtering.
S103, forming an anode layer on the planarization layer. Specifically, the anode layer can be formed by, for example, deposition, and the anode layer can be patterned by photolithography, etching, or the like.
S104, forming a pixel definition layer on the planarization layer and the anode layer, wherein the pixel definition layer includes linear pixel grooves and dot-shaped dummy pixel grooves. Specifically, the pixel definition layer may be composed of organic materials such as acrylic resin, and a plurality of linear pixel grooves and a plurality of dot-shaped dummy pixel grooves are formed through processes such as patterning and curing.
S105, forming a hole injection layer on the anode layer in the pixel grooves and the dummy pixel grooves by inkjet printing.
S106, checking whether printing volumes for forming the hole injection layer in the dummy pixel grooves is normal, if yes, proceeding to a next step, if not, stopping production and checking nozzles.
S107, performing a drying treatment on the hole injection layer. Specifically, the drying treatment can be carried out by heating, baking, or the like.
S108, forming a hole transport layer on the hole injection layer by inkjet printing.
S109, checking whether printing volumes for forming the hole transport layer in the dummy pixel grooves is normal, if yes, proceeding to a next step, if not, stopping the production and checking the nozzles.
S110, performing a drying treatment to the hole transport layer. Specifically, the drying treatment can be carried out by heating, baking, or the like.
S111, forming a luminescent material layer on the hole transport layer by inkjet printing.
S112, checking whether printing volumes for forming the luminescent material layer in the dummy pixel grooves is normal, if yes, proceeding to a next step, if not, stopping the production and checking the nozzles.
S113, performing a drying treatment on the luminescent material layer. Specifically, the drying treatment can be carried out by heating, baking, or the like.
S114, forming an electron transport layer on the luminescent material layer. Specifically, the electron transport layer can be formed by evaporation or the like.
S115, forming an electron injection layer on the electron transport layer. Specifically, the electron injection layer may be formed by evaporation or the like.
S116, forming a cathode layer on the electron injection layer. Specifically, the cathode layer may be formed by evaporation or the like.

As described above, in the foregoing embodiment of the present invention, dummy pixel units are provided outside at least one side of the pixel unit rows, or pixel dot sub-portions are formed at the outermost pixel unit at one end of each pixel unit row, wherein the pixel dot sub-portion occupies ⅓ to ½ of an area of the pixel electrode. Through the method to provide the aforesaid small dummy pixel units or the pixel dot sub-portions, it is easy to monitor whether the inkjet volume of each nozzle is normal during the process of inkjet printing. Therefore, it can solve the problem that in the current inkjet printing technology for the OLED devices, it is not possible to monitor whether the inkjet volume of each nozzle is normal because the linear pixel film layer is formed by mixing inks dispensed from multiple nozzles, which leads to low production yield due to insufficient film thickness or uneven film thickness of the entire batch of products.

The above descriptions are preferred embodiments of the present invention. It is noted that for those of ordinary skill in the art, without departing from the principle of the present invention, several improvements and modifications can be made, and these improvements and modifications should also be regarded as the protection scope of the present invention.

What is claimed is:

1. An organic light-emitting diode substrate, comprising:
a substrate;
a thin film transistor element layer disposed on the substrate;
an anode layer disposed on the thin film transistor element layer, wherein the anode layer comprises pixel electrodes arranged in an array and dummy pixel electrodes, and each pixel electrode is electrically connected to a corresponding thin-film transistor in the thin film transistor element layer;
a pixel definition layer, wherein the pixel definition layer is defined with linear pixel grooves and dot-shaped dummy pixel grooves on the anode layer;
a light-emitting functional layer disposed on the anode layer in the pixel grooves and the dummy pixel grooves; and
a cathode layer disposed on the light-emitting functional layer, wherein
the pixel electrodes, the light-emitting functional layer, and the cathode layer form a plurality of pixel unit rows under definition of the pixel grooves, and the dummy pixel electrodes, the light-emitting functional layer, and the cathode layer form a plurality of dummy pixel units under definition of the dummy pixel grooves.

2. The organic light-emitting diode substrate of claim 1, further comprising a buffer layer disposed between the thin film transistor element layer and the anode layer.

3. The organic light-emitting diode substrate of claim 1, wherein the light-emitting functional layer comprises a hole injection layer, a hole transport layer, a luminescent material layer, an electron transport layer, and an electron injection layer.

4. The organic light-emitting diode substrate of claim 1, wherein the dummy pixel units are arranged outside an upper side and/or a lower side of the plurality of pixel unit rows.

5. The organic light-emitting diode substrate of claim 4, further comprising another dummy pixel units arranged outside a left side and/or a right side of the plurality of pixel unit rows.

6. The organic light-emitting diode substrate of claim 5, wherein the dummy pixel units are arranged outside the left side and/or the right side of the plurality of pixel unit rows in a way that one dummy pixel unit corresponds to one pixel unit row.

7. The organic light-emitting diode substrate of claim 5, wherein the dummy pixel units are arranged outside the left side and/or the right side of the plurality of pixel unit rows in a way that two dummy pixel units correspond to one pixel unit row.

8. The organic light-emitting diode substrate of claim 7, wherein the two dummy pixel units are arranged side by side.

9. The organic light-emitting diode substrate of claim 7, wherein types of luminescent material layers of the two dummy pixel units are same.

10. An organic light-emitting diode substrate, comprising:
a substrate;
a thin film transistor element layer disposed on the substrate;
an anode layer disposed on the thin film transistor element layer, wherein the anode layer comprises pixel electrodes arranged in an array, and each pixel electrode is electrically connected to a corresponding thin-film transistor in the thin film transistor element layer;
a pixel definition layer, wherein the pixel definition layer is defined with linear first pixel grooves and dot-shaped second pixel grooves on the anode layer;
a light-emitting functional layer disposed on the anode layer in the first pixel grooves and the second pixel grooves; and
a cathode layer disposed on the light-emitting functional layer;
wherein the pixel electrodes, the light-emitting functional layer, and the cathode layer form a plurality of pixel unit rows under definition of the first pixel grooves; and
wherein a part of an outermost pixel electrode at one end of each pixel unit row is located in the first pixel groove, and a remaining part of the pixel electrode is located in the second pixel groove to form a pixel dot sub-portion.

11. The organic light-emitting diode substrate of claim 10, wherein the pixel dot sub-portion occupies ⅓ to ½ of an area of the pixel electrode.

12. The organic light-emitting diode substrate of claim 10, further comprising a buffer layer disposed between the thin film transistor element layer and the anode layer.

13. The organic light-emitting diode substrate of claim 10, wherein the light-emitting functional layer comprises a hole injection layer, a hole transport layer, a luminescent material layer, an electron transport layer, and an electron injection layer.

14. A manufacturing method of an organic light-emitting diode substrate, comprising:
providing a substrate and forming a thin film transistor element layer on the substrate;
forming a planarization layer on the thin film transistor element layer;
forming an anode layer on the planarization layer;
forming a pixel definition layer on the planarization layer and the anode layer, wherein the pixel definition layer comprises linear pixel grooves and dot-shaped dummy pixel grooves;
forming a hole injection layer on the anode layer in the pixel grooves and the dummy pixel grooves by inkjet printing;
checking whether printing volumes for forming the hole injection layer in the dummy pixel grooves is normal, if yes, proceeding to a next step, if not, stopping production and checking nozzles;
performing a drying treatment on the hole injection layer;
forming a hole transport layer on the hole injection layer by inkjet printing;
checking whether printing volumes for forming the hole transport layer in the dummy pixel grooves is normal, if yes, proceeding to a next step, if not, stopping the production and checking the nozzles;
performing a drying treatment on the hole transport layer;
forming a luminescent material layer on the hole transport layer by inkjet printing;
checking whether printing volumes for forming the luminescent material layer in the dummy pixel grooves is normal, if yes, proceeding to a next step, if not, stopping the production and checking the nozzles;
performing a drying treatment on the luminescent material layer;
forming an electron transport layer on the luminescent material layer;
forming an electron injection layer on the electron transport layer; and
forming a cathode layer on the electron injection layer.
